(19) United States
(12) Patent Application Publication
(10) Pub. No.: US 2001/0043125 A1
(43) Pub. Date: Nov. 22, 2001

(54) Oscillator

(75) Inventor: Fumitoshi Sato, Yasu-gun (JP)

Correspondence Address: OSTROLENK FABER GERB & SOFFEN, 1180 AVENUE OF THE AMERICAS, NEW YORK, NY, 100368403

(73) Assignee: Murata Manufacturing Co., Ltd.

(21) Appl. No.: 09/731,004

(22) Filed: Dec. 6, 2000

(30) Foreign Application Priority Data
May 16, 2000 (JP) 2000-143686

(51) Int. Cl. H03B 5/12; H03B 5/18

(52) U.S. Cl. 331/117 R; 331/117 D; 331/167; 331/177 V

(57) ABSTRACT

An oscillator with reduced phase noise. The oscillator includes a resonance circuit and an amplifying circuit. The amplifying circuit has an amplifier. An impedance element having a frequency characteristic is connected to the amplifier and, therefore, the power amplification of the amplifying circuit is decreased by at least 3 dB in a frequency band lower than about 0.5 times an oscillating frequency f₀ or higher than about 2f₀, as compared to the power amplification of said amplifying circuit at the oscillating frequency f₀.

### BACKGROUND OF THE INVENTION

1. Field of the Invention

The present invention relates to an oscillator, more particularly, to an oscillator comprising, for example, a resonance circuit and an amplifying circuit.

2. Description of the Related Art

FIG. 24 is a schematic diagram showing an example of a conventional oscillator. An oscillator 1 in FIG. 24 comprises a resonance circuit 2 and an amplifying circuit 3. In the oscillator 1, an oscillating signal is frequency-selected by the resonance circuit 2. The loss caused by the resonance circuit 2 is compensated by the amplifying circuit 3, thereby continuing the oscillation. Referring to FIG. 24, it is assumed that the signal power inputted to the amplifying circuit 3 is set to Pᵢₙ and the power outputted from the amplifying circuit 3 is set to Pₒᵤₜ, and then the power amplification of the amplifying circuit 3 is represented as Pₒᵤₜ/Pᵢₙ.

The circuit shown in FIG. 25 is an example of the oscillator 1. The oscillator 1 includes a parallel circuit of a capacitor C1 and an inductor L1. The parallel circuit is connected to a power supply voltage Vc. Further, a cathode of a variable capacitance diode D1 is connected to the parallel circuit, and an anode thereof is connected to ground. One end of a capacitor C2 is connected to the connection point of the parallel circuit and the variable capacitance diode D1. Other capacitors C3 and C4 and a microstrip line SL1 are connected at one end to the other end of the capacitor C2. The other ends of the capacitor C3 and the microstrip line SL1 are connected to ground. The thus-constructed circuit constitutes the resonance circuit 2.

The other end of the capacitor C4 is connected to a base of an NPN transistor Tr1 constituting the amplifying circuit 3. Also a voltage obtained by dividing the power supply voltage Vc by a series circuit of resistors R1, R2, and R3 is inputted to the base of the NPN transistor Tr1. Another voltage divided by the resistors R1, R2, and R3 is inputted to a base of another NPN transistor Tr2. The power supply voltage Vc is connected to a collector of the transistor Tr2 via an inductor L2 and an emitter thereof is connected to a collector of the transistor Tr1. A resistor R4 and a capacitor C5 are connected at one end to an emitter of the transistor Tr1, and the other ends thereof are connected to ground.

The bases of the transistors Tr1 and Tr2 are connected to the emitter of the transistor Tr1 via capacitors C6 and C7, respectively. Further, the collectors of the transistors Tr1 and Tr2 are connected to ground via capacitors C8 and C9, respectively. The collector of the transistor Tr2 is connected to a capacitor 10, and an output signal is obtained through the capacitor C10. The amplifying circuit 3 comprises the transistor Tr1, resistors R2, R3, and R4, capacitors C5, C6, and C8, and the other components just described.

Another example of an oscillator circuit is shown in FIG. 26. The resonance circuit 2 and the amplifying circuit 3 are the same as those in FIG. 25. In the oscillator 1, an output signal of the amplifying circuit 3 is inputted to a base of another transistor Tr3 via a capacitor C11. A voltage divided by a dividing circuit comprising resistors R5 and R6 is inputted to the transistor Tr3. Further, a collector of the transistor Tr3 is connected to the power supply voltage Vc through an inductor L3 and an emitter thereof is connected to ground through a resistor R7 and a capacitor C12. Capacitors C13 and C14 are connected to the collector of the transistor Tr3, the capacitor C13 is connected to ground, and an output signal is obtained via the capacitor C14. The oscillators 1 shown in FIGS. 25 and 26 are examples of oscillators using NPN transistors, and the use of these oscillators 1 results in obtaining an oscillating output.

However, the amplifying circuit amplifies signals even outside the intended oscillating frequency band, so that a higher harmonic wave component and an unnecessary wave component of the oscillator are amplified together, thereby causing deterioration of the oscillator's performance due to phase noise.

### SUMMARY OF THE INVENTION

To address this problem, the present invention provides an oscillator with reduced phase noise.

According to the present invention, there is provided an oscillator comprising a resonance circuit and an amplifying circuit, in which an element having a frequency characteristic is provided in the amplifying circuit, thereby decreasing power amplification of said amplifying circuit in a frequency band away from an oscillating frequency by at least 3 dB lower than the power amplification of said amplifying circuit at the oscillating frequency f₀.

Preferably the 3 dB bandwidth is substantially 0.5 f₀ to 2f₀.

The element may be constituted by a single unit selected from an inductor, a capacitor, and a microstrip line, or by combining a plurality of units from among an inductor, a capacitor, a microstrip line, and a resistor.

The element having a frequency characteristic may also be made of a dielectric or piezoelectric material such as a dielectric resonator (or filter), a crystal oscillator (or filter), a ceramic oscillator (or filter), and a surface acoustic wave resonator (or filter).

At least one of the resonance circuit and the amplifying circuit may be an MMIC. Further, the oscillator may comprise a peripheral circuit, and at least one of said resonance circuit, said amplifying circuit, and said peripheral circuit may be formed as an MMIC.

The resonance circuit and the amplifying circuit may be integrally formed on a resin substrate or a ceramic substrate to form a module. Further, the oscillator may comprise a peripheral circuit, and the resonance circuit, the amplifying circuit, and the peripheral circuit may be integrally formed on the resin substrate or ceramic substrate.

In the oscillator, an amplifying circuit using an NPN transistor can be employed. Then, the element having the frequency characteristic can be provided between an emitter of the NPN transistor and ground, thereby decreasing the power amplification in a frequency band other than an oscillating frequency.

The element with the frequency characteristic is built into the amplifier and, therefore, the power amplification of the amplifier has a frequency characteristic. Accordingly, by decreasing the power amplification in a frequency band remote from the desired oscillating frequency f₀, preferably outside the range from about 0.5f₀ to about 2f₀, by 3 dB or more, as compared with the power amplification at the oscillating frequency, the oscillation signal at the oscillating frequency is amplified and the amplification in a frequency band other than at the oscillating frequency can be suppressed.

The above and other features and advantages of the present invention will become more apparent from the following description of embodiments of the invention, with reference to the accompanying drawings.

### BRIEF DESCRIPTION OF THE DRAWINGS

FIG. 1 is a schematic diagram showing a first example of an oscillator according to the present invention;

FIG. 2 is a graph showing the power amplification of an amplifier used for the oscillator shown in FIG. 1 and the power amplification of an amplifying circuit in which an impedance element having a frequency characteristic is connected to the amplifier;

FIG. 3 is a schematic diagram showing a second example of the oscillator according to the present invention;

FIG. 4 is a schematic diagram of a third example of the oscillator according to the present invention;

FIG. 5 is a schematic diagram of a fourth example of the oscillator according to the present invention;

FIG. 6 is a schematic diagram of a fifth example of the oscillator according to the present invention;

FIG. 7 is a circuit diagram showing one example of an oscillator according to the present invention;

FIG. 8 is a circuit diagram showing another example of an oscillator according to the present invention;

FIG. 9 is a circuit diagram showing one example in which a parallel circuit of a resistor and a capacitor is connected in series with a parallel circuit of a capacitor and an inductor as an impedance element of the oscillator shown in FIG. 7;

FIG. 10 is a circuit diagram showing one example in which a parallel circuit of a resistor and a capacitor is connected in series with a parallel circuit of a capacitor and an inductor as an impedance element of the oscillator shown in FIG. 8;

FIG. 11 is a circuit diagram showing one example in which a series circuit of a capacitor and an inductor is added to the impedance element in the oscillator shown in FIG. 9, thereby forming an impedance element;

FIG. 12 is a circuit diagram showing one example in which a series circuit of a capacitor and an inductor is added to the impedance element in the oscillator shown in FIG. 10, thereby forming an impedance element;

FIG. 13 is a circuit diagram showing one example in which a parallel circuit of a resistor and a capacitor is connected in series to a parallel circuit of a capacitor and a microstrip line as an impedance element of the oscillator shown in FIG. 7;

FIG. 14 is a circuit diagram showing one example in which a series circuit of a capacitor and a microstrip line is added to the impedance element in the oscillator shown in FIG. 13, thereby forming an impedance element;

FIG. 15 is a circuit diagram showing one example in which a plurality of series circuits of a capacitor and an inductor are added to the impedance element in the oscillator shown in FIG. 12, thereby forming an impedance element;

FIG. 16 is a circuit diagram showing one example using an impedance element which is formed by a dielectric or piezoelectric material as the impedance element in the oscillator shown in FIG. 7;

FIG. 17 is a circuit diagram showing one example in which a resistor is added to the impedance element in the oscillator shown in FIG. 16, thereby forming an impedance element;

FIG. 18 is a schematic diagram showing one example of an oscillator wherein an amplifying circuit is formed in an MMIC;

FIG. 19 is a schematic diagram showing one example of an oscillator wherein a resonance circuit and an amplifying circuit are formed entirely in an MMIC;

FIG. 20 is a circuit diagram showing one example wherein the amplifying circuit in the oscillator shown in FIG. 7, a buffer circuit, and a bias circuit are formed in an MMIC;

FIG. 21 is a schematic diagram showing one example further comprising a peripheral circuit, and formed entirely in an MMIC;

FIG. 22 is a schematic diagram showing one example of an oscillator wherein the resonance circuit and the amplifying circuit are formed entirely on a substrate, thereby forming a module;

FIG. 23 is a schematic diagram showing one example further comprising a peripheral circuit, and formed entirely on the substrate, thereby forming a module;

FIG. 24 is a schematic diagram showing one example of a conventional oscillator;

FIG. 25 is a circuit diagram showing another example of a conventional oscillator; and

FIG. 26 is a circuit diagram showing yet another example of a conventional oscillator.

### DESCRIPTION OF EMBODIMENTS OF THE INVENTION

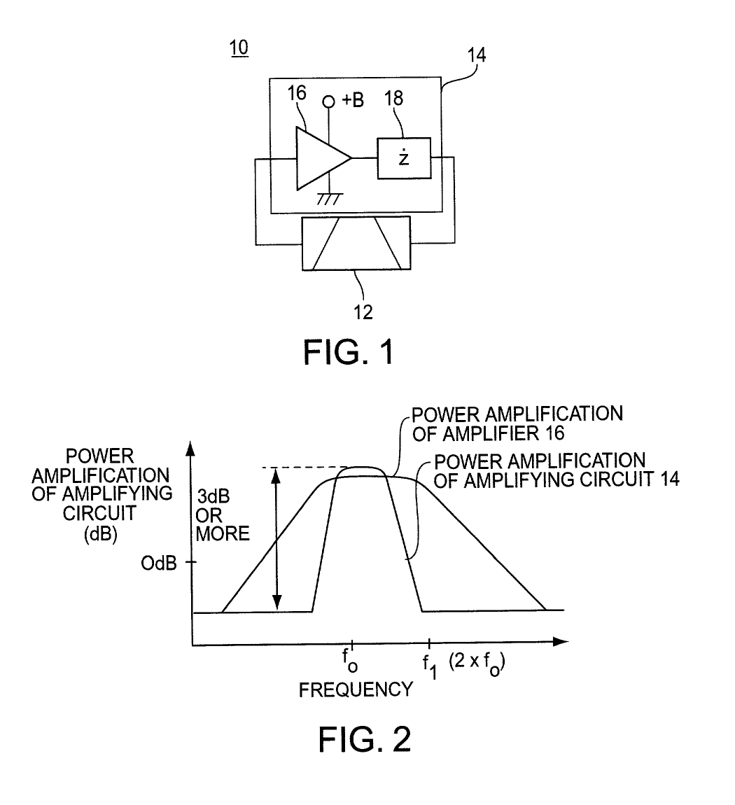

FIG. 1 is a schematic diagram showing a first example of an oscillator according to the present invention. An oscillator 10 comprises a resonance circuit 12 and an amplifying circuit 14. The amplifying circuit 14 has an amplifier 16, and the amplifier 16 is connected to a power supply voltage +B and ground. The resonance circuit 12 and the amplifying circuit 14 is connected in a loop form. In this case, an impedance element 18 having a frequency characteristic is connected to the amplifier 16 in the amplifying circuit 14. Referring to FIG. 1, the impedance element 18 is mounted to an output side of the amplifier 16. The impedance element 18 may be an inductor, a capacitor, or a microstrip line, etc. constituting a single unit. The impedance element 18 having the frequency characteristic may also be a combination of two or more of the inductor, capacitor, and microstrip line, and/or a resistor. Further, it is sufficient to utilize, as the impedance element 18, an element with a frequency characteristic comprising a dielectric or piezoelectric material, such as a dielectric resonator (or filter), a crystal oscillator (or filter), a ceramic oscillator (or filter), and a surface acoustic wave resonator (or filter).

According to the oscillator 10, the impedance element 18 with the frequency characteristic allows the amplifying circuit 14 to have a frequency characteristic. That is, by connecting the impedance element 18, the power amplification in a certain frequency band can be selectively decreased. Therefore, as shown in FIG. 2, when using only the amplifier 16 to which the impedance element with a frequency characteristic is not connected, the power amplification remains high across a wide frequency band. When using the amplifying circuit 14 to which the impedance element 18 having a frequency characteristic is connected, the power amplification can be lower in frequency bands disposed substantially away from an oscillating frequency f₀ in the oscillator 10. Herein, the impedance element 18 is selected so as to decrease the power amplification in a frequency band substantially remote from the oscillating frequency f₀ in the oscillator 10 by at least 3 dB, that is, above about a frequency of (2×f₀), and/or below about (0.5×f₀), as compared with the power amplification at an oscillating frequency f₀ of the oscillator 10. Thus the 3 dB bandwidth of the impedance element is (2f₀)−(0.5f₀).

As seen in FIG. 2, it is not necessary for the characteristics of the amplifier to be symmetric about frequency f₀, and it is also not necessary for the maximum amplification to occur at frequency f₀.

According to the oscillator 10, the resonance circuit 12 selects a frequency of oscillation. The loss caused by the resonance circuit 12 is compensated by the amplifying circuit 14, thereby continuing the oscillation. Since the power amplification of the amplifying circuit 14 varies depending upon frequency, the power at the oscillating frequency is amplified up to the maximum, and the power amplification is suppressed in the frequency bands above and below the oscillating frequency. Therefore, in this oscillator the noise level which is superposed by unnecessary waves such as a high-degree higher harmonic waves of the oscillating frequency is decreased, thereby reducing the phase noise of the oscillator 10.

In this circuit, no power is consumed generating the unnecessary oscillating component of the signal amplified by the amplifying circuit 14, thereby increasing its oscillating efficiency and reducing its power consumption. Further, a high-degree higher harmonic component of the oscillating frequency is decreased, to thereby reduce unnecessary radiation.

A further advantage is that the oscillator 10 can be miniaturized. The Q of a resonance circuit using a microstrip line or chip coil is generally proportional to an electrode width in the microstrip line or the size of the chip coil. However, since the phase noise can be diminished by the amplifying circuit 14, good results can be obtained even with a lower-Q resonance circuit 12 in which a microstrip line has a narrower electrode width or in which a chip coil is smaller.

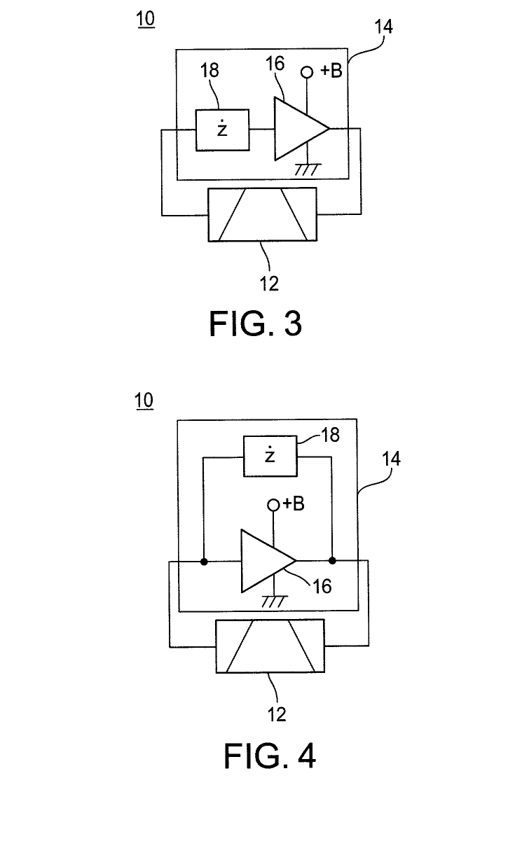

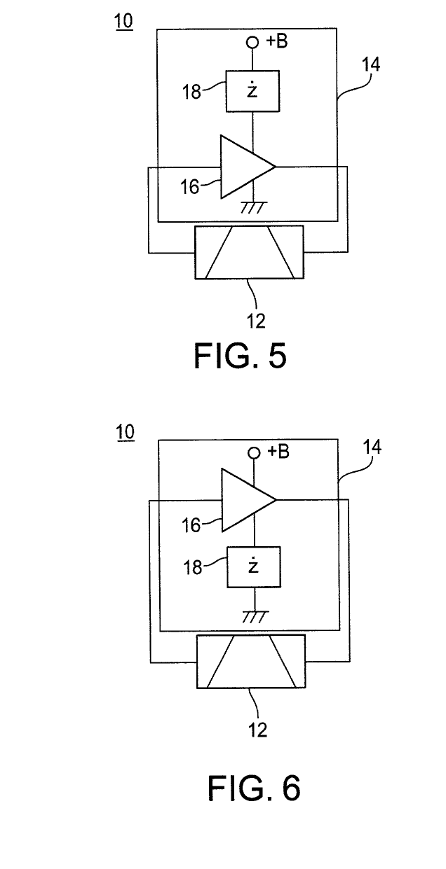

Note that as shown in FIG. 3, the impedance element 18 may be connected to an input side of the amplifier 16 in the amplifying circuit 14. As shown in FIG. 4, the impedance element 18 also may be connected between the input side and an output side of the amplifier 16. Further, as shown in FIG. 5 the impedance element 18 also may be connected between the amplifier 16 and the power supply voltage +B. Furthermore, as shown in FIG. 6 the impedance element 18 also may be connected between the amplifier 16 and ground. Thus, the connection configuration of the impedance element 18 is not limited. So long as a connection configuration causes the power amplification of the amplifying circuit 14 to have a frequency characteristic, any connection arrangement can be employed.

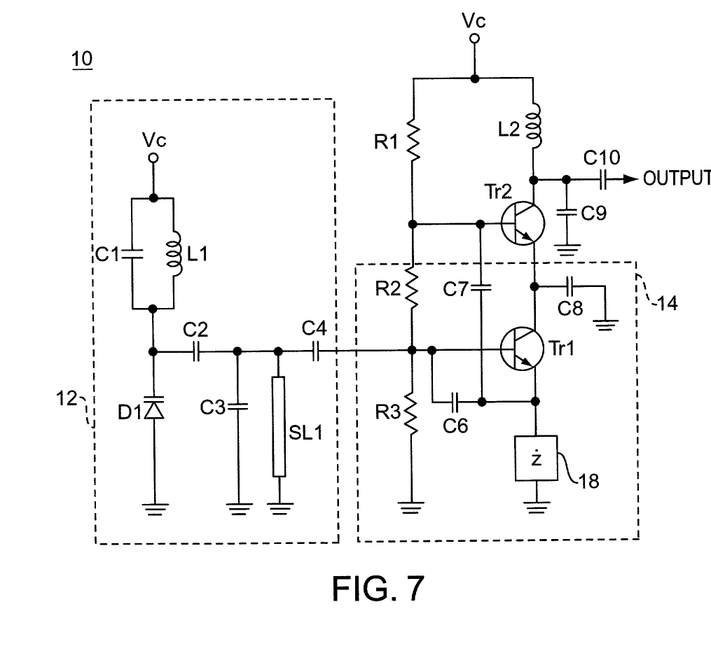

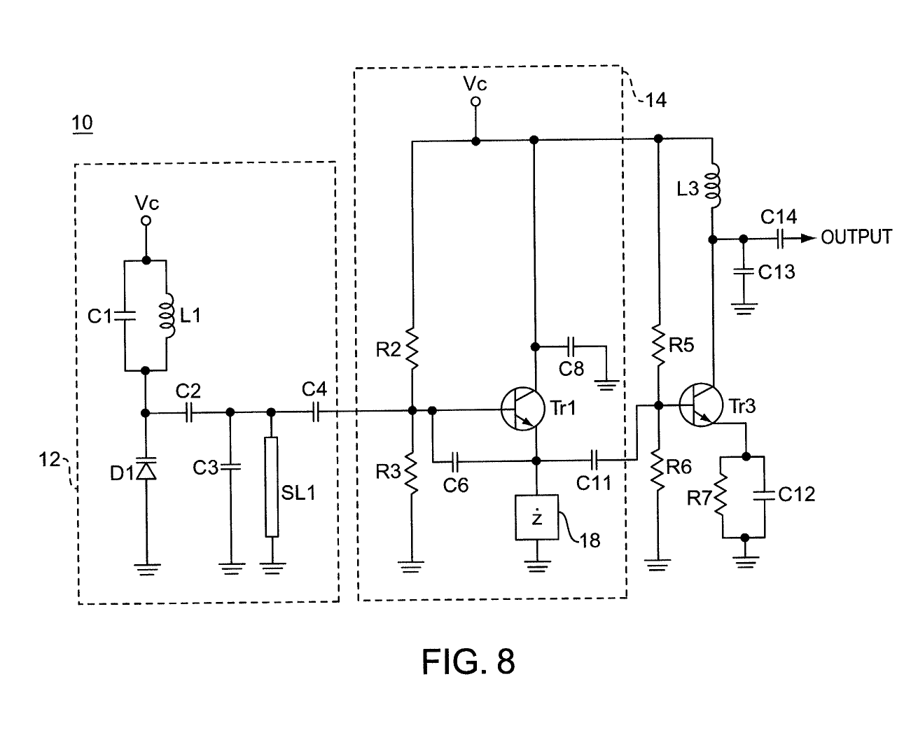

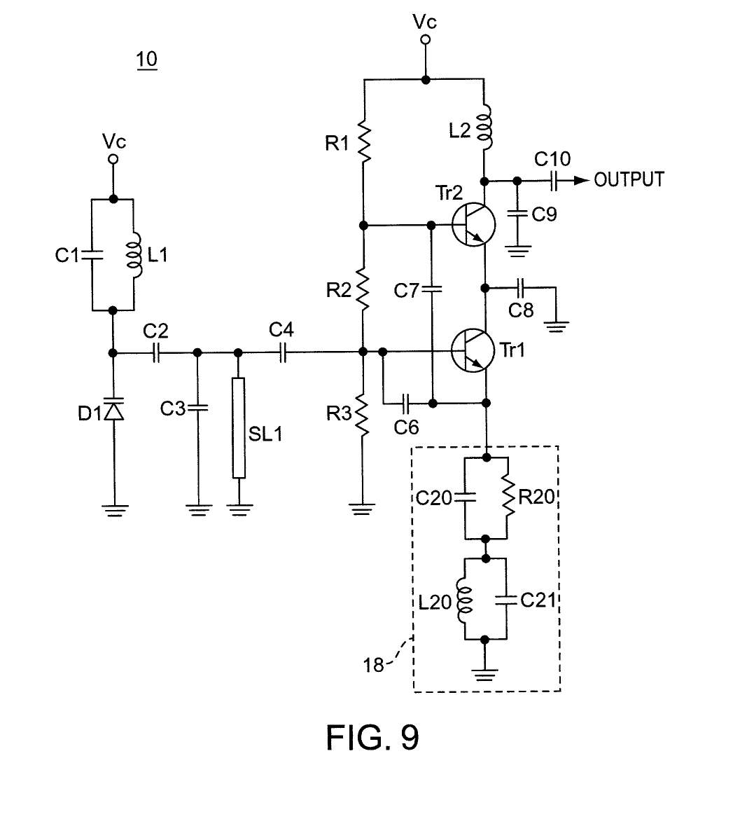

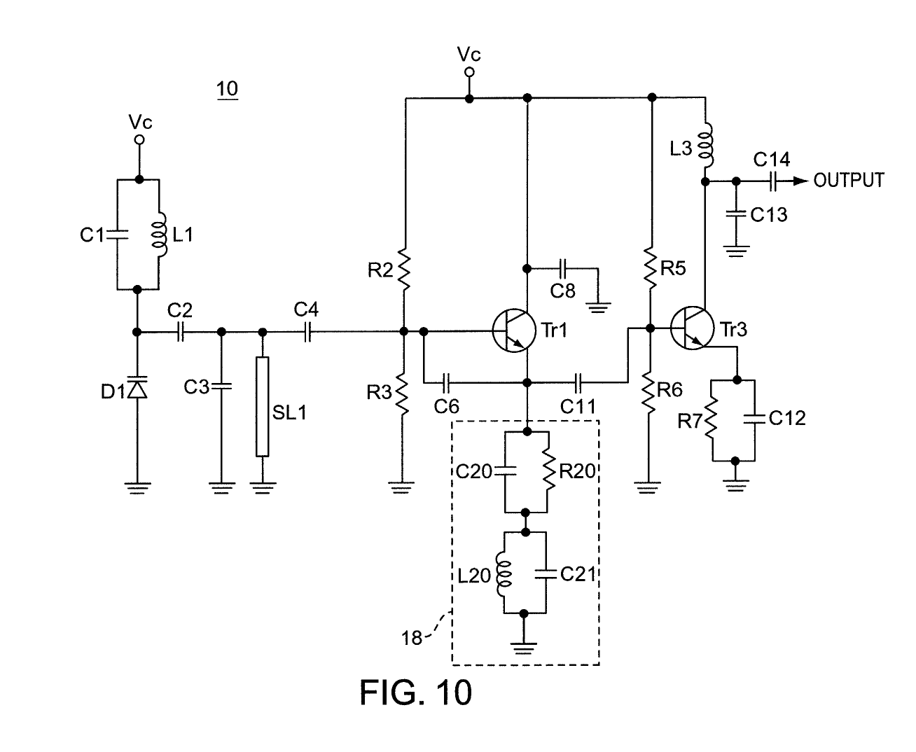

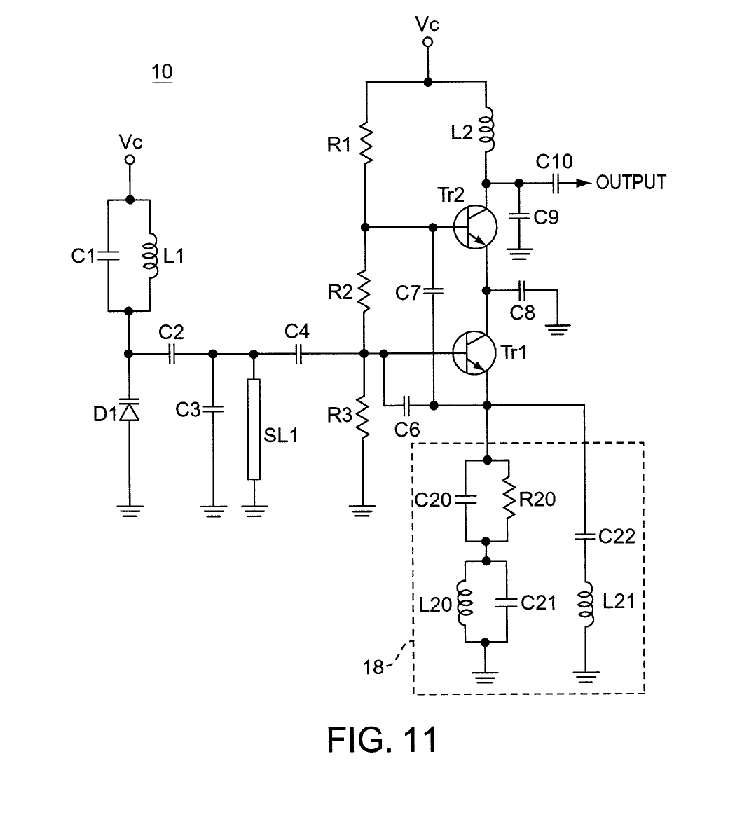

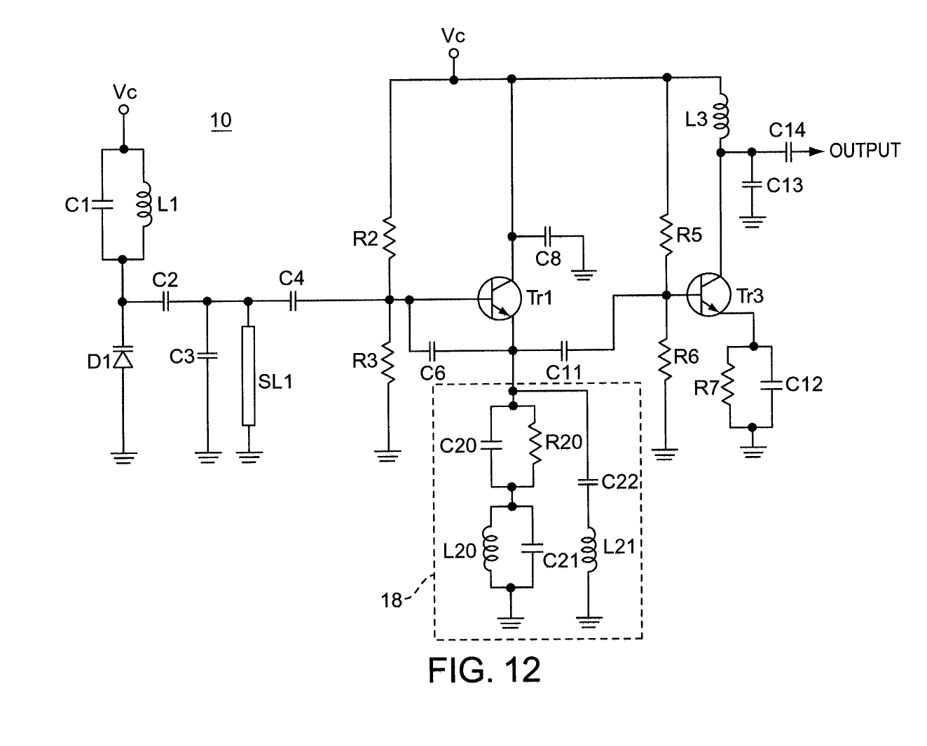

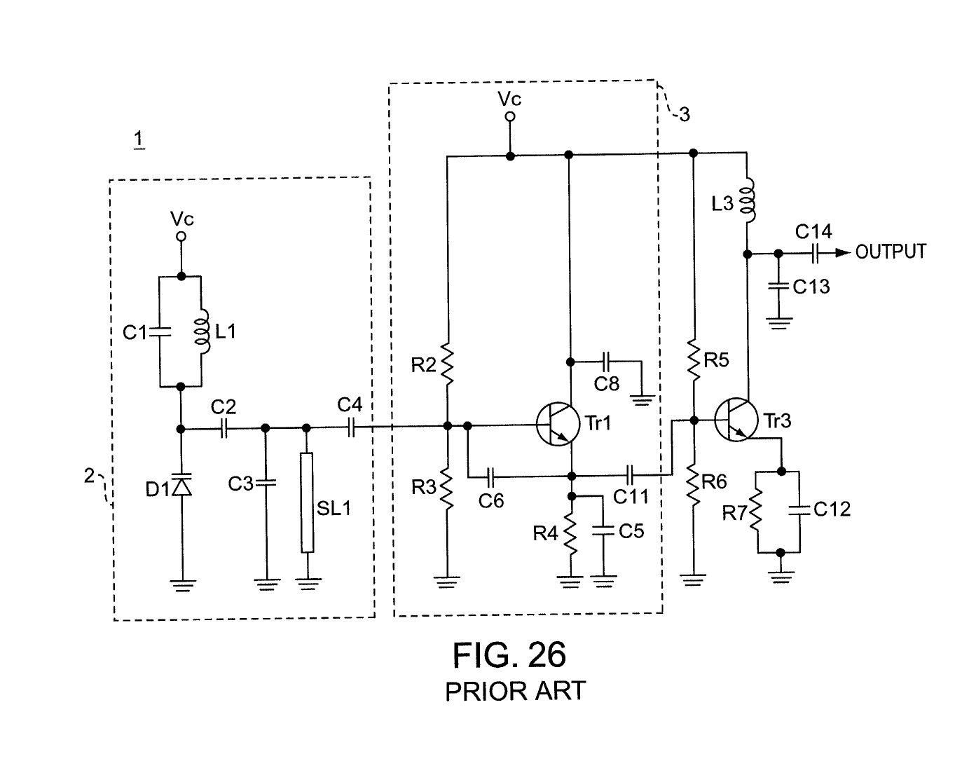

In embodiments of the present invention based on the circuits shown in FIG. 26 and FIG. 27, the impedance element 18 having a frequency characteristic is connected between the emitter of the transistor Tr1 constituting the amplifying circuit 14 and ground, as shown in FIGS. 7 and 8. As shown in FIGS. 9 and 10, respectively, the impedance element 18 may be a series circuit which is obtained by connecting in series a parallel circuit of a DC bias resistor R20 and a capacitor 20, and a parallel resonance circuit of an inductor L20 and a capacitor 21. As shown FIGS. 11 and 12, respectively, a series circuit of a capacitor 22 and an inductor 21 may be further added, and the series circuit is connected to the emitter of the transistor Tr1 in the circuit shown in FIGS. 9 and 10.

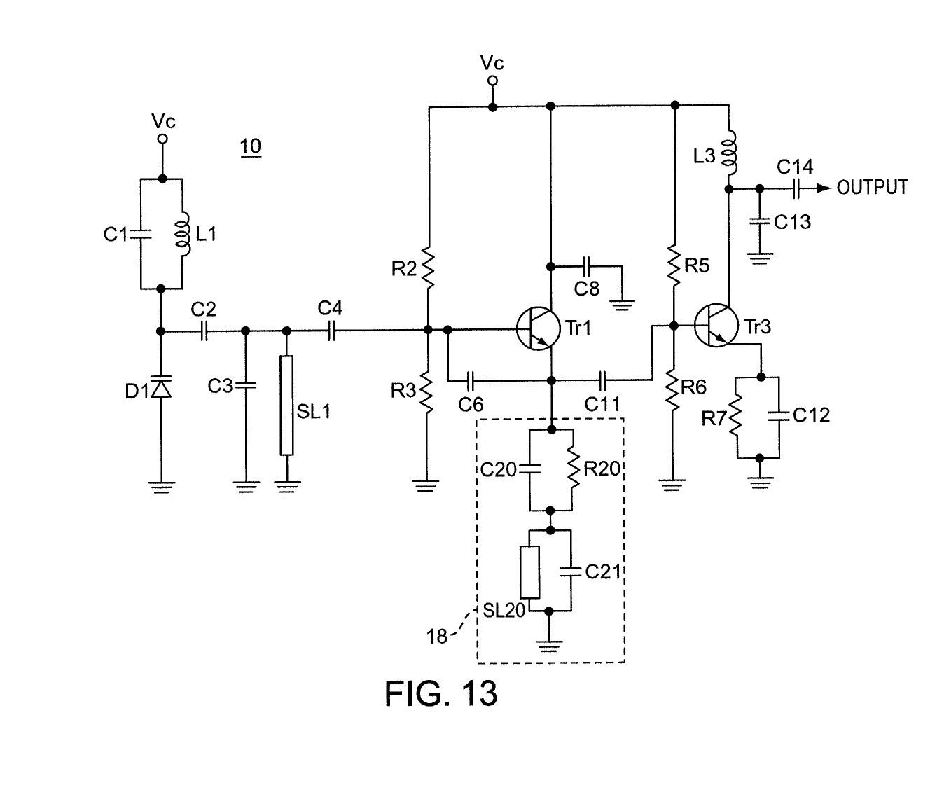

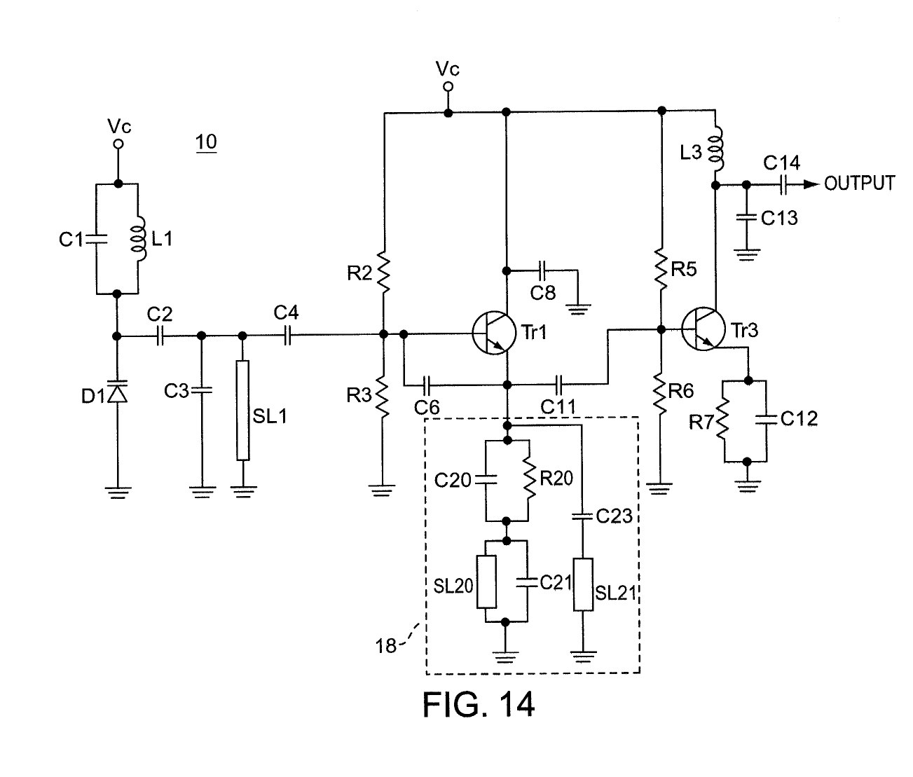

As shown in FIG. 13, the impedance element 18 may be a series circuit which is obtained by connecting in series a parallel circuit of the DC bias resistor R20 and the capacitor 20 and a parallel circuit of a microstrip line SL20 and the capacitor 21. As shown in FIG. 14, a series circuit of a capacitor C23 and a microstrip line SL21 may be connected to the emitter of the transistor Tr1 in the circuit shown in FIG. 13. With respect to FIGS. 13 and 14, although the basic circuit corresponds to FIG. 8, the same modifications may be applied similarly to a circuit corresponding to FIG. 7.

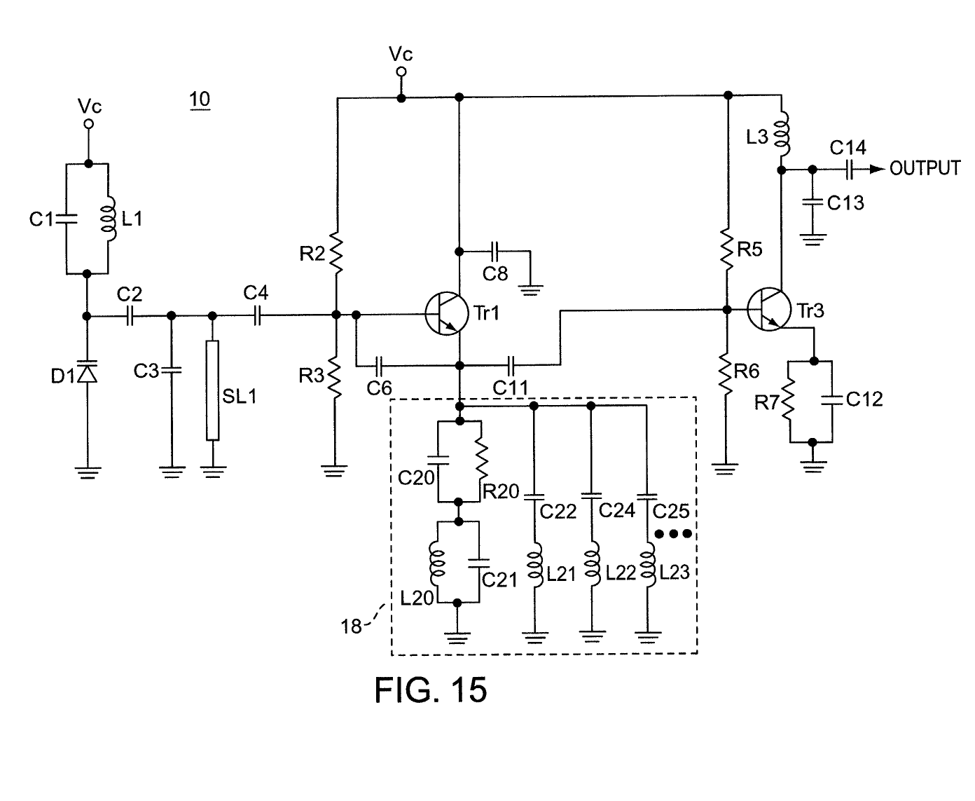

As shown in FIG. 15, in addition to the series circuit of the capacitor C22 and the inductor L21 in the circuit shown in FIG. 12, one or more additional series circuits each comprising a capacitor and an inductor may be connected in parallel. For example, a series circuit of a capacitor C24 and an inductor L22, and a series circuit of a capacitor C25 and an inductor L23 may be connected in parallel. Of course, it is understood also that one or more additional series circuits of a capacitor and an inductor can be connected in parallel to the emitter of the transistor Tr1 in the circuit of the oscillator 10 shown in FIG. 11.

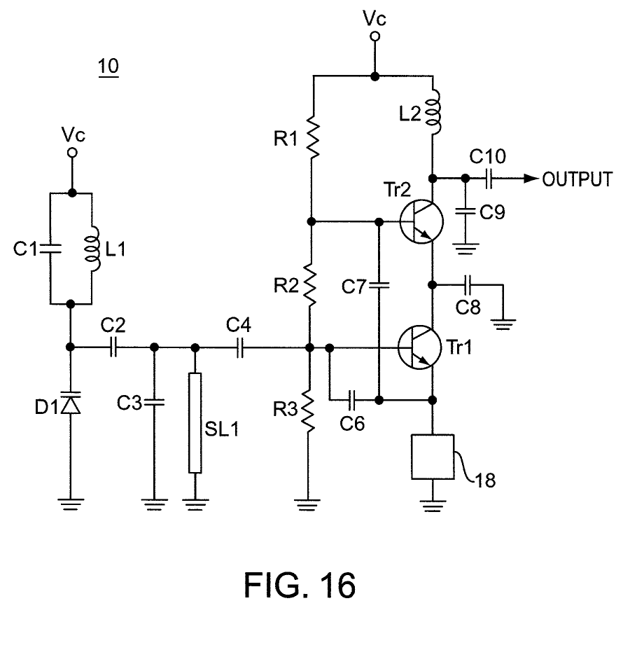

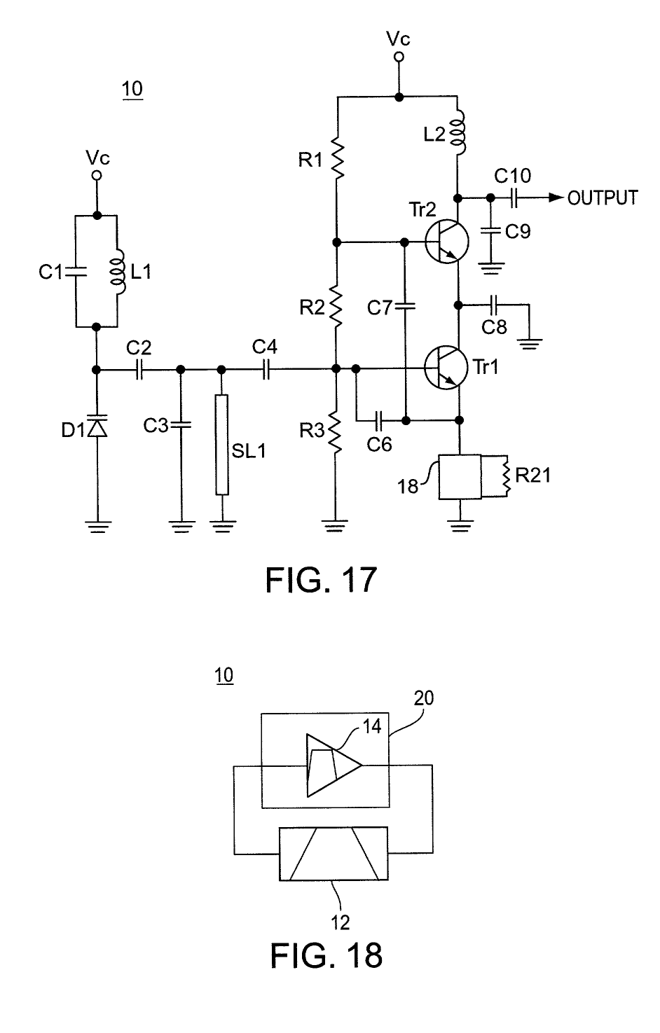

In FIG. 16, which is based on the circuit of FIG. 7, the element 18 having the frequency characteristic may be made of a dielectric or piezoelectric material and may be connected to the emitter of the transistor Tr1 constituting the amplifying circuit 14. Moreover, as shown in FIG. 17, a resistor 21 may be added in parallel with the element 18. The elements 18 of FIGS. 16 and 17 may also be applied to the circuit shown in FIG. 8. The element 18 formed by a dielectric or piezoelectric material may be an element such as a dielectric resonator (or filter), a crystal oscillator (or filter), a ceramic oscillator (or filter), or a surface acoustic wave resonator (or filter).

In the foregoing embodiments of the invention, the power amplification of the amplifying circuit 14 is made to exhibit a frequency characteristic by providing the impedance element 18 having the frequency characteristic between the emitter of the transistor Tr1 which constitutes the amplifying circuit 14 in the oscillator 10 and ground. Thus, it is possible to reduce the power amplification in a frequency band away from the oscillating frequency of the oscillator 10, thereby decreasing a superposed noise level due to unnecessary waves such as harmonics of the oscillating frequency and reducing the phase noise of the oscillator 10.

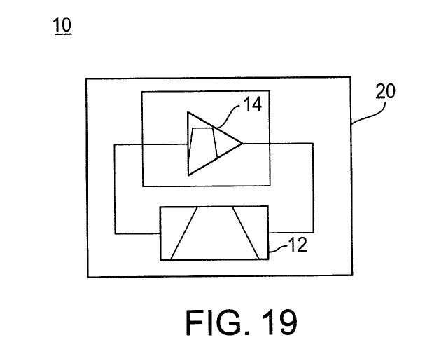

As shown schematically in FIG. 18, a coil, a capacitor, a transistor, etc. may be formed on a wafer chip whereby the amplifying circuit 14 may be formed as an MMIC 20. Of course, the amplifying circuit 14 formed into the MMIC 20 shows the frequency characteristic. In other words, the amplifier 16 and the impedance element 18 are integrated in the single MMIC 20, and thus, the oscillator 10 with a small size and a low-phase noise is obtained. Further, as shown schematically in FIG. 19, both the resonance circuit 12 and the amplifying circuit 14 may be formed in the single MMIC 20. According to the foregoing, the MMIC 20 can comprise the entire oscillator 10, whereby the oscillator 10 can be further miniaturized.

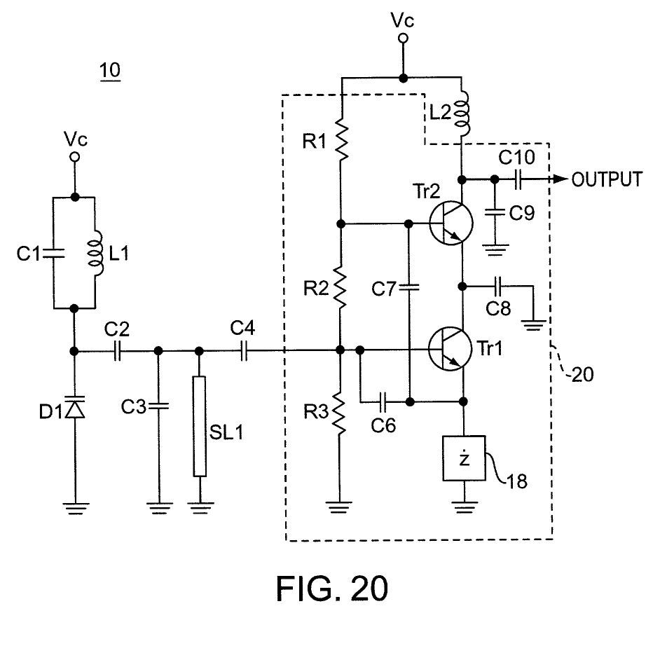

FIG. 20 is a specific example of a circuit in which a part of the oscillator 10 is incorporated into an IC. That is, the amplifying circuit, a buffer circuit, and a bias circuit are integrated in the single MMIC 20, as shown in FIG. 20.

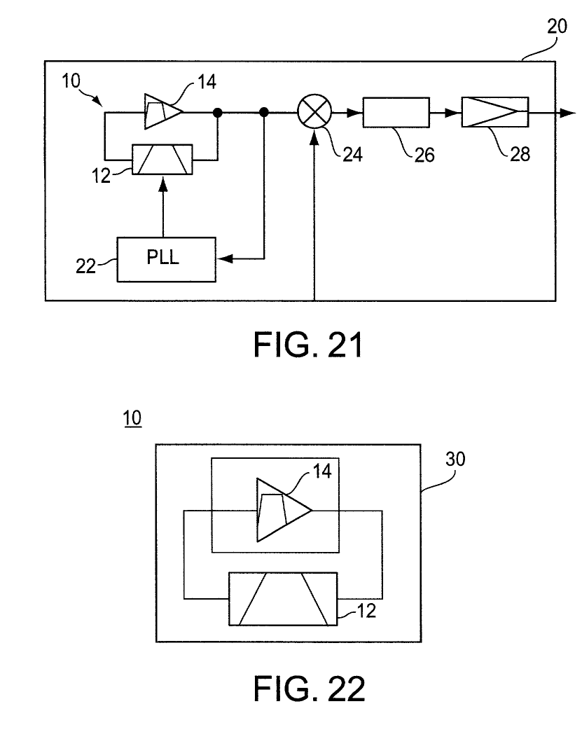

As shown in FIG. 21, the MMIC 20 may be constructed with a peripheral circuit added to the oscillator 10. Referring to FIG. 21, a phase locked loop (PLL) 22 is added to the oscillator 10 and an output of the oscillator 10 is connected to a mixer 24. The mixer 24 is connected to a resonator 26 and the resonator 26 is also connected to an amplifier 28. All of those circuits are incorporated into the single MMIC 20. Thus an oscillator having an added value is obtained. The obtained circuit can be employed as a local oscillator, a mixer, and an intermediate frequency amplifying circuit in communication equipment.

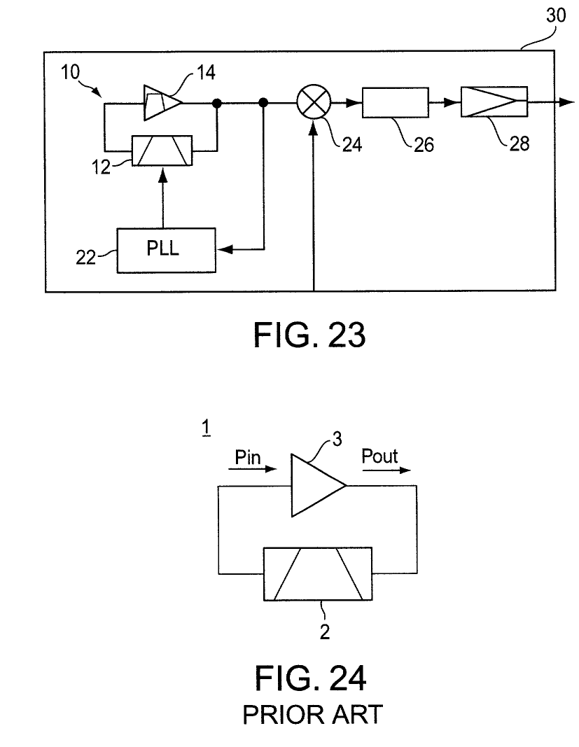

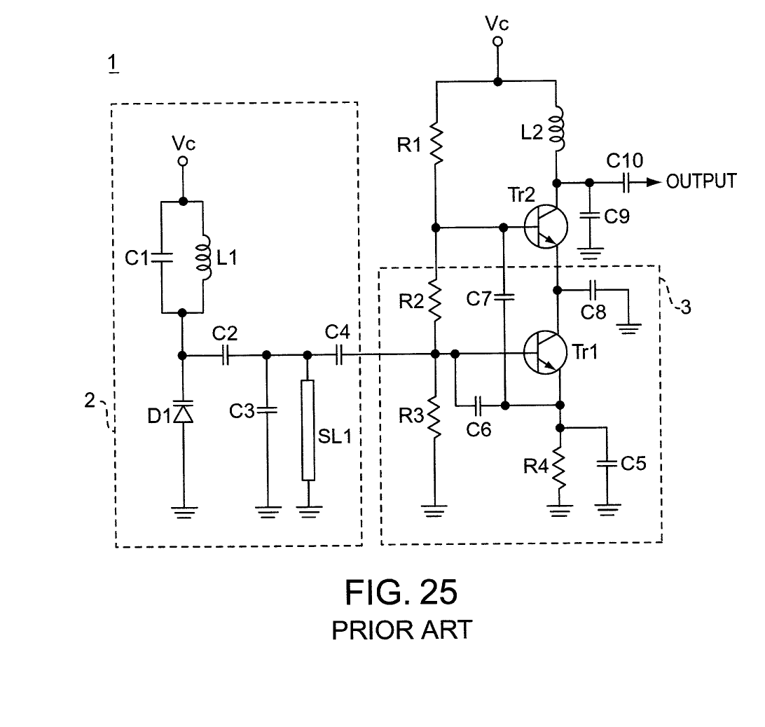

As shown in FIG. 22, the amplifying circuit 14 and the resonance circuit 12 may be integrally formed on a substrate 30, thus, a module is constructed. As the substrate 30, a ceramic substrate or a resin substrate, etc. are used. In case of using the ceramic substrate, the substrate can be a multi-layer substrate and it is also possible for electronic components constituting the resonance circuit and amplifying circuit to be incorporated within the multi-layer substrate. Moreover, it is possible for the substrate 30 to incorporate not only the oscillator 10, but also to integrally form the peripheral circuits such as the PLL20, mixer 24, resonator 26, and amplifier 28 on the substrate 30 and form a module, as shown in FIG. 23.

As explained above, it is possible according to the invention to miniaturize the oscillator 10 such that the oscillator 10 is incorporated into an IC or a module. That is, the amplifying circuit 14 shown schematically in FIGS. 18 and 19 and 21 to 23 is formed by combining the amplifier 16 with the impedance element 18 having the frequency characteristic and it can adopt any one of the connection configurations shown FIGS. 1 and 3 to 6.

According to the present invention, the power amplification in a frequency band other than near the oscillating frequency of an oscillator is low, so that it is possible to decrease a noise level which is superposed on a frequency component other than the desired oscillation frequency, and also to reduce the harmonic wave level in the oscillator output. As mentioned above, the harmonic components of the oscillating frequency are decreased, so that unnecessary radiation can be reduced. Since no power is supplied to generate an unnecessary oscillating component of a signal amplified by an amplifying circuit, the oscillation efficiency increases and the power consumption decreases. Further, the phase noise is improved on the amplifying circuit side and, therefore, the Q of the resonance circuit can be improved. It is also possible to decrease a line width in a microstrip line in a resonator, to miniaturize a chip coil, and to reduce the overall size of the oscillator. By making the oscillator an IC or by making the oscillator as a module, an oscillator having an even smaller size can be obtained.

Although embodiments of the invention have been explained, the invention is not limited thereto, but extends to all modifications, variations and alternate uses that would occur to those having the ordinary level of skill in the pertinent art.

What is claimed is:

1. An oscillator having a resonance circuit connected to an amplifying circuit,
wherein said amplifying circuit comprises an element having a frequency characteristic, thereby decreasing power amplification of said amplifying circuit by at least 3 dB in a frequency band lower than about 0.5 times an oscillating frequency f₀ or higher than about 2f₀, as compared to the power amplification of said amplifying circuit at the oscillating frequency f₀.

2. An oscillator according to claim 1, wherein said element is constituted by a single unit selected from among an inductor, a capacitor, and a microstrip line; or by a combination of a plurality of units selected from among an inductor, a capacitor, a microstrip line, and a resistor.

3. An oscillator according to claim 1, wherein said element comprises a dielectric or piezoelectric material and has a frequency characteristic.

4. An oscillator having a resonance circuit connected to an amplifying circuit,
wherein said amplifying circuit comprises an element having a frequency characteristic, thereby decreasing power amplification of said amplifying circuit by at least 3 dB in a frequency band lower than about 0.5 times an oscillating frequency f₀ or higher than about 2f₀, as compared to the power amplification of said amplifying circuit at the oscillating frequency f₀, and
wherein at least one of said resonance circuit and said amplifying circuit is comprised in an MMIC.

5. An oscillator according to claim 4, further comprising a peripheral circuit, wherein at least one of said resonance circuit, said amplifying circuit, and said peripheral circuit is comprised in an MMIC.

6. An oscillator having a resonance circuit connected to an amplifying circuit,
wherein said amplifying circuit comprises an element having a frequency characteristic, thereby decreasing power amplification of said amplifying circuit by at least 3 dB in a frequency band lower than about 0.5 times an oscillating frequency f₀ or higher than about 2f₀, as compared to the power amplification of said amplifying circuit at the oscillating frequency f₀, and
wherein said resonance circuit and said amplifying circuit are integrally formed on a resin substrate or a ceramic substrate.

7. An oscillator according to claim 6, further comprising a peripheral circuit, wherein said resonance circuit, said amplifying circuit, and said peripheral circuit are integrally formed on a resin substrate or a ceramic substrate.

8. An oscillator according to claim 1, wherein said amplifying circuit comprises an NPN transistor and said element is provided between an emitter of said NPN transistor and ground.
